(19) United States
(12) Patent Application Publication
(10) Pub. No.: US 2006/0108585 A1
(43) Pub. Date: May 25, 2006

(54) Thin film transistors and fabrication methods thereof

(75) Inventors: Feng-Yuan Gan, Hsinchu City (TW); Han-Tu Lin, Wuci Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/143,405

(22) Filed: Jun. 2, 2005

(30) Foreign Application Priority Data
Nov. 22, 2004 (TW) 93135850

(51) Int. Cl. H01L 29/76

(52) U.S. Cl. 257/66

(57) ABSTRACT

Thin film transistors and fabrication methods thereof. A gate is formed overlying a portion of a substrate. A gate-insulating layer is formed overlying the gate. A vanadium oxide layer is formed between the gate and the substrate and/or the gate and the gate-insulating layer. A semiconductor layer is formed on a portion of the gate-insulating layer. A source and a drain are formed on a portion of the semiconductor layer.

### BACKGROUND

The invention relates to thin film transistors, and more particularly, to gate structures of thin film transistors.

Bottom-gate type thin film transistors (TFTs) are widely used for thin film transistor liquid crystal displays (TFT-LCDs). FIG. 1 is a sectional view of a conventional bottom-gate type TFT structure 100. The TFT structure 100 typically comprises a glass substrate 110, a gate 120, a gate-insulating layer 130, a channel layer 140, an ohmic contact layer 150, a source 160 and a drain 170.

As the size of TFT-LCD panels increase, metals having rather low resistance are required. For example,,gate lines employ low resistance metals such as Cu and Cu alloy in order to improve operation of the TFT-LCD. However, Cu has unstable properties such as poor adhesion with the glass substrate. The poor adhesion causes a film-peeling problem. Cu also has a tendency to diffuse into a gate-insulating film (such as silicon-oxide film) and to affect the quality of TFT device. Moreover, Cu is vulnerable to deformation due to its weakness. Specifically, in a plasma process (such as plasma enhanced chemical vapor deposition, PECVD) for depositing a film, some characteristic degradations such as roughness and resistance of Cu are increased due to a reaction with Cu and the gas of the plasma process.

U.S. Pat. No. 6,165,917 to Batey et al., the entirety of which is hereby incorporated by reference, describes a method for passivating Cu. The method uses an ammonia-free silicon nitride layer as a cap layer covering a Cu gate.

U.S. Publication No. 2002/0042167 to Chae, the entirety of which is hereby incorporated by reference, describes a method of forming a TFT. A metal layer such as Ta, Cr, Ti or W is deposited on a substrate. A Cu gate is defined on the metal layer. A thermal oxidation process is then performed to diffuse the material of the metal layer along the surface of the Cu gate. A metallic oxide caused by the thermal treatment thus surrounds the Cu gate. The metallic oxide is tantalum oxide, chrome oxide, titanium oxide or tungsten oxide.

U.S. Pat. No. 6,562,668 to Jang et al., the entirety of which is hereby incorporated by reference, describes a method of forming a TFT. The method uses an aluminum oxide or aluminum nitride layer as an adhesion layer between a Cu gate and a glass substrate and a cap layer covering the Cu gate.

### SUMMARY

Thin film transistors and fabrication methods thereof are provided. An exemplary embodiment of a thin film transistor is provided. A vanadium oxide layer overlies a substrate. A gate is disposed on a portion of the vanadium oxide layer. A gate-insulating layer overlies the gate and the vanadium oxide layer. A semiconductor layer overlies a portion of the gate-insulating layer. A source and a drain are disposed on a portion of the semiconductor layer.

Another embodiment of a thin film transistor is provided. A gate is disposed on a portion of a substrate. A vanadium oxide layer overlies the gate and the substrate. A gate-insulating layer overlies the vanadium oxide layer. A semiconductor layer overlies a portion of the gate-insulating layer. A source and a drain are disposed on a portion of the semiconductor layer.

Yet another embodiment of a thin film transistor is provided. A first vanadium oxide layer overlies a substrate. A gate is disposed on a portion of the first vanadium oxide layer. A second vanadium oxide layer overlies the gate and the first vanadium oxide layer. A gate-insulating layer overlies the second vanadium oxide layer. A semiconductor layer overlies a portion of the gate-insulating layer. A source and a drain are disposed on a portion of the semiconductor layer.

A vanadium oxide layer is formed between the gate and the substrate and/or the gate and the gate-insulating layer. Thus, the gate has exceptional adhesion with the substrate by means of the vanadium oxide layer. In addition, the vanadium oxide layer prevents deformation of the gate during subsequent plasma processes, thereby increasing device yield.

### DESCRIPTION OF THE DRAWINGS

The invention can be more fully understood by reading the subsequent detailed description in conjunction with the examples and references made to the accompanying drawings, wherein

FIG. 1 is a sectional view of a conventional TFT structure;

FIGS. 2A-2D are sectional views illustrating an exemplary process for fabricating a first embodiment of a TFT structure of the present invention;

FIGS. 3A-3D are sectional views illustrating an exemplary process for fabricating a second embodiment of a TFT structure of the present invention; and

FIGS. 4A-4D are sectional views illustrating an exemplary process for fabricating a third embodiment of a TFT structure of the present invention.

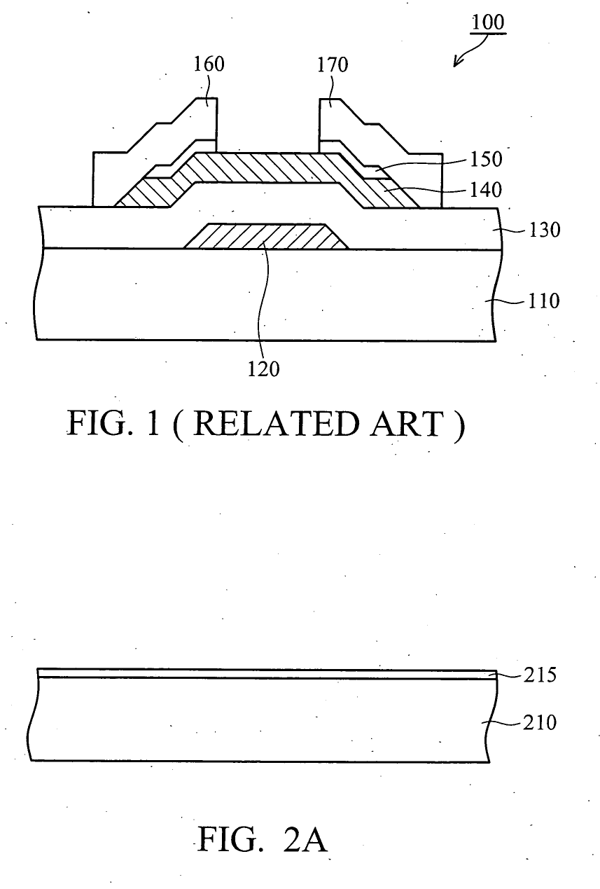

### DETAILED DESCRIPTION

### First Embodiment

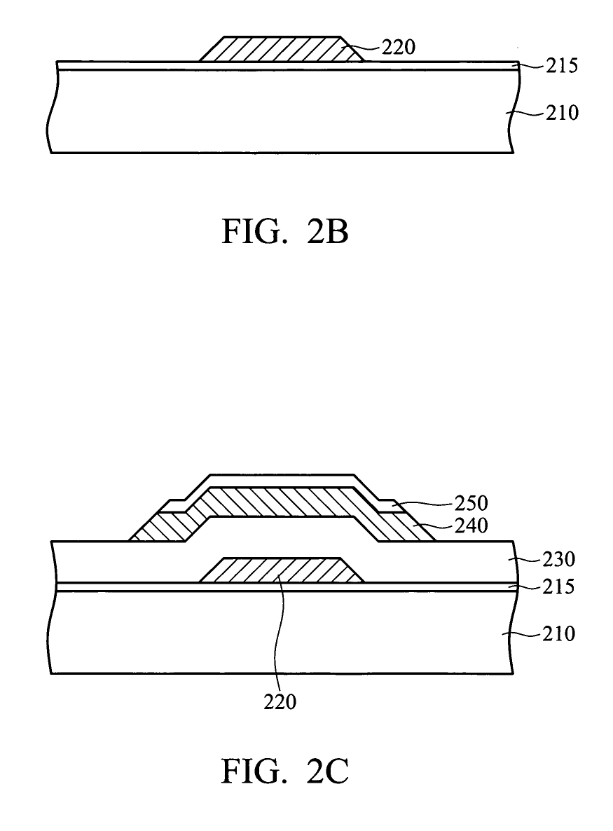

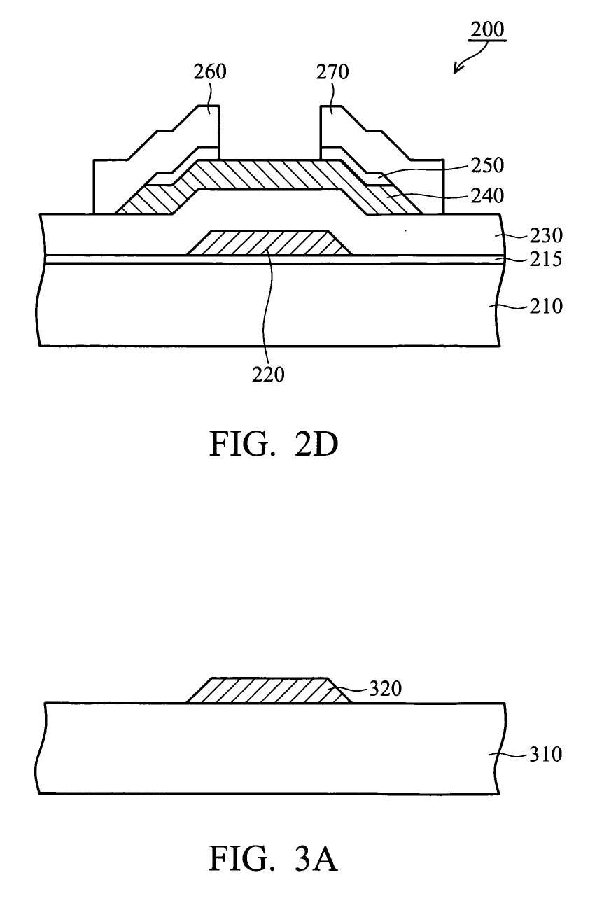

Thin film transistors (TETs) and fabrication methods thereof are provided. The thin film transistors can be bottom-gate type TFTs, top-gate type TFTs or others. For convenience, representative bottom-gate type TFT structures are illustrated, but are not intended to limit the disclosure. An exemplary process for fabricating a first embodiment of a TFT structure of the present invention is shown in FIGS. 2A-2D.

In FIG. 2A, a vanadium oxide layer 215 is formed on a substrate 210 by, for example, CVD (chemical vapor deposition) or PVD (physical vapor deposition). The substrate 210 may be a glass, quartz or transparent polymer substrate. An exemplary method of forming the vanadium oxide layer 215 is illustrated in the following. The substrate 210 is disposed in a reactive ion-sputtering chamber using a vanadium target. In the reactive sputtering, oxygen and argon are introduced into the chamber to deposit the vanadium oxide layer 215 on the substrate 210. The chemical formula of vanadium oxide (VₓO_{y}) can be VO, VO₂, V₂O₃ or V₂O₅. The thickness of the vanadium oxide layer 215 can be substantially in a range of about 30 Å to about 1000 Å, preferably, substantially in a range of about 50 Å to about 200 Å.

In FIG. 2B, a gate 220 is formed on a portion of the vanadium oxide layer 215 by sputtering and patterning. The gate 220 can be a metal layer comprising Cu, Al, Mo, Ag, Ag—Pd—Cu, Cr, W, Ti, metal alloy thereof or multi-layer thereof. Since the vanadium oxide layer 215 is between the gate 220 and the substrate 210, adhesion therebetween is increased.

In FIG. 2C, a gate-insulating layer 230 is formed on the gate 220 and the vanadium oxide layer 215 by, for example, CVD or PVD. The gate-insulating layer 230 can be a silicon oxide, silicon nitride, silicon oxynitride, tantalum oxide or aluminum oxide layer. The gate-insulating layer 230 can also be an organic layer with a protective function. The organic layer may comprise a compound containing Si, O and C, a compound containing Si, O, C and H, a compound containing Si and C, a compound containing C and F, or a substantially starburst-shaped compounds containing center of C or F.

In FIG. 2C, a semiconductor layer comprising a channel layer 240 and an ohmic contact layer 250 is defined on a portion of the gate-insulating layer 230 by deposition and patterning. The channel layer 240 can be an amorphous silicon layer formed by CVD. The ohmic contact layer 250 can be an impurity-added silicon layer formed by CVD. The impurity can be n type dopant (for example P or As) or p type dopant (for example B).

In FIG. 2D, a source 260 and a drain 270 are formed on a portion of the semiconductor layer formed by sputtering and patterning. The source 260 and drain 270 can be metal comprising Al, Mo, Cr, W, Ta, Ti, Ni, metal alloy thereof or multi-layer thereof. Using the source 260 and drain 270 as a mask, the exposed ohmic contact layer 250 is then etched away. A TFT structure 200 is thus obtained.

The first embodiment of the TFT structure 200 of the present invention, shown in FIG. 2D, comprises a vanadium oxide layer 215 formed on a substrate 210. A gate 220 is formed on a portion of the vanadium oxide layer 215. A semiconductor layer 240/250 is formed on a portion of the gate-insulating layer 230. A source 260 and a drain 270 are formed on a portion of the semiconductor layer 240/250.

When the TFT structure 200 is applied in the TFT-LCD panel, the gate 220 and the gate line of the array substrate can be formed simultaneously. Thus, the vanadium oxide layer 215 can be disposed between the gate line and the substrate 210. To avoid obscuring aspects of the disclosure, description of detailed formation of the TFT-LCD panel is omitted here.

### Second Embodiment

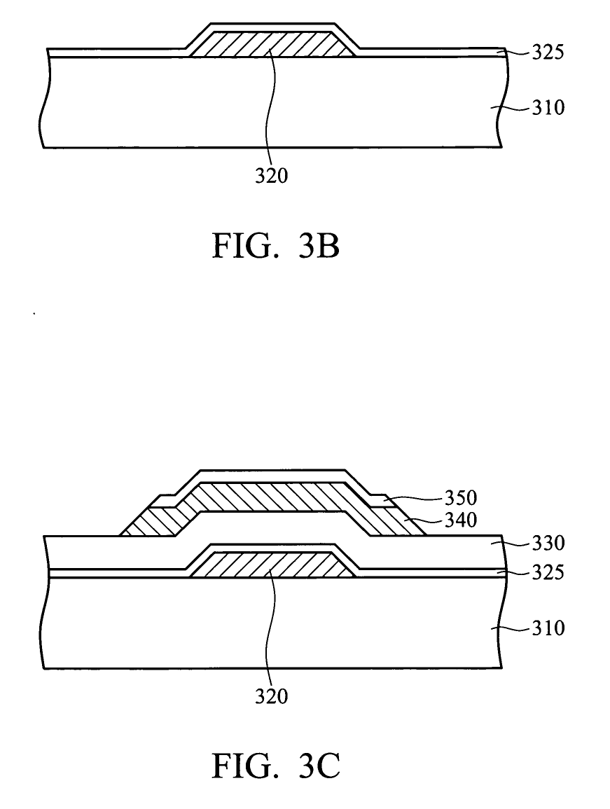

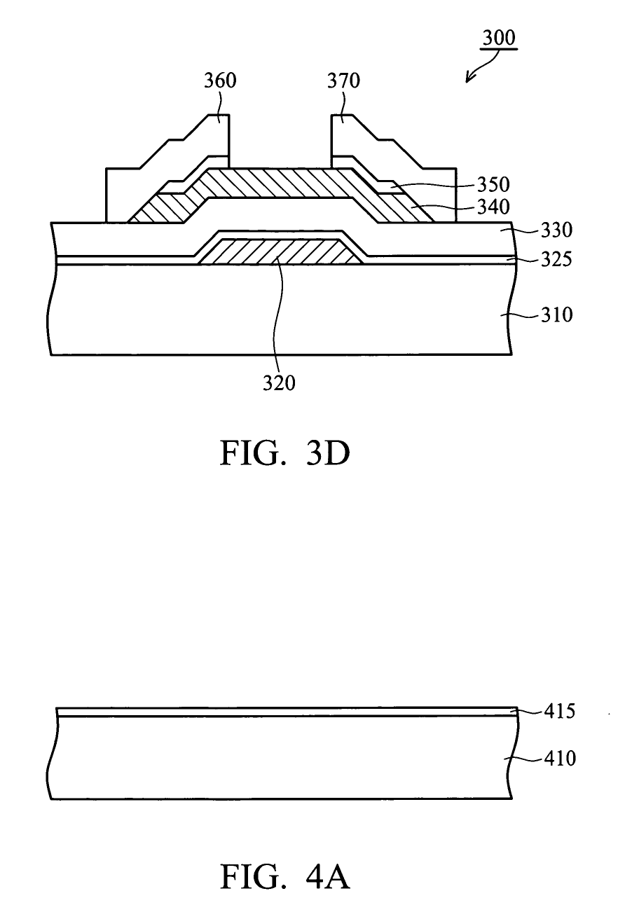

The thin film transistors can be bottom-gate type TFTs, top-gate type TFTs or others. For convenience, representative bottom-gate type TFT structures are illustrated, but are not intended to limit the disclosure. An exemplary process for fabricating a second embodiment of a TFT structure of the present invention is illustrated in FIGS. 3A-3D. In FIG. 3A, a gate 320 is formed on a portion of a substrate 310 by sputtering and patterning. The gate 320 can be a metal layer comprising Cu, Al, Mo, Ag, Ag—Pd—Cu, Cr, W, Ti, metal alloy thereof or multi-layer thereof. The substrate 310 may be a glass, quartz or transparent polymer substrate.

In FIG. 3B, a vanadium oxide layer 325 is formed on the gate 320 and the substrate 310 by CVD or PVD. An exemplary method of forming the vanadium oxide layer 325 is illustrated in the following. The substrate 310 comprising the gate 320 is disposed in a reactive ion-sputtering chamber using a vanadium target. In the reactive sputtering, oxygen and argon are introduced into the chamber to deposit the vanadium oxide layer 325 on the gate 320 and the substrate 310. The chemical formula of vanadium oxide (VₓO_{y}) can be VO, VO₂, V₂O₃ or V₂O₅. The thickness of the vanadium oxide layer 325 can be substantially in a range of about 30 Å to about 1000 Å, preferably, substantially in a range of about 50 Å to about 200 Å.

In FIG. 3C, a gate-insulating layer 330 is formed on the vanadium oxide layer 325 by, for example, deposition. The gate-insulating layer 330 can be a silicon oxide, silicon nitride, silicon oxynitride, tantalum oxide or aluminum oxide layer. The gate-insulating layer 330 can also be an organic layer with a protective function. The organic layer may comprise a compound containing Si, O and C, a compound containing Si, O, C and H, a compound containing Si and C, a compound containing C and F, or a substantially starburst-shaped compounds containing center of C or F. Since the vanadium oxide layer 325 is between the gate 320 and the gate-insulating layer 330, the vanadium oxide layer 325 prevents deformation of the gate 320 during subsequent plasma processes for depositing gate-insulating layers.

In FIG. 3C, a semiconductor layer comprising a channel layer 340 and an ohmic contact layer 350 is defined on a portion of the gate-insulating layer 330 by deposition and patterning. The channel layer 340 can be an amorphous silicon layer formed by CVD. The ohmic contact layer 350 can be an impurity-added silicon layer formed by CVD. The impurity can be n type dopant (for example P or As) or p type dopant (for example B).

In FIG. 3D, a source 360 and a drain 370 are formed on a portion of the semiconductor layer formed by sputtering and patterning. The source 360 and drain 370 can be metal layers comprising Al, Mo, Cr, W, Ta, Ti, Ni, metal alloy thereof or multi-layer thereof. Using the source 360 and drain 370 as a mask, the exposed ohmic contact layer 350 is then removed by etching. A TFT structure 300 is thus obtained.

The second embodiment of the TFT structure 300 of the present invention, shown in FIG. 3D, comprises a gate 320 disposed on a portion of a substrate 310. A vanadium oxide layer 325 is formed on the substrate 310 and the gate 320. A gate-insulating layer 330 is formed on a vanadium oxide layer 325. A semiconductor layer 340/350 is formed on a portion of the gate-insulating layer 330. A source 360 and a drain 370 are formed on a portion of the semiconductor layer 340/350.

When the TFT structure 300 is applied in the TFT-LCD panel, the gate 320 and the gate line of the array substrate can be formed simultaneously. Thus, the vanadium oxide layer 325 can also be formed between the gate line and the gate-insulating layer 330. To avoid obscuring aspects of the disclosure, description of detailed formation of the TFT-LCD panel is omitted here.

### Third Embodiment

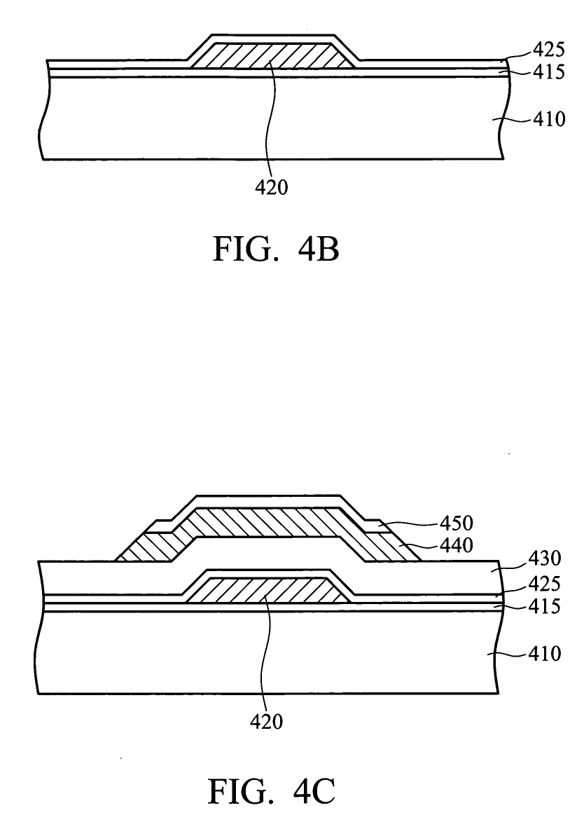

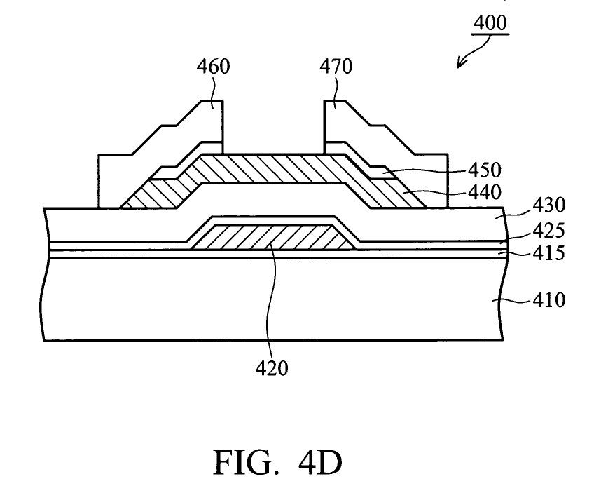

The thin film transistors can be bottom-gate type TFTs, top-gate type TFTs or others. For convenience, representative bottom-gate type TFT structures are illustrated, but are not intended to limit the disclosure. An exemplary process for fabricating a third embodiment of a TFT structure of the present invention is illustrated-in FIGS. 4A-4D. In FIG. 4A, a first vanadium oxide layer 415 is formed on a substrate 410 by, for example, CVD or PVD. The substrate 410 may be a glass, quartz or transparent polymer substrate. An exemplary method of forming the first vanadium oxide layer 415 is illustrated in the following. The substrate 410 is disposed in a reactive ion-sputtering chamber using a vanadium target. In the reactive sputtering, oxygen and argon are introduced into the chamber to deposit the first vanadium oxide layer 415 on the substrate 410. The chemical formula of vanadium oxide (VₓO_{y}) can be VO, VO₂, V₂O₃ or V₂O₅. The thickness of the first vanadium oxide layer 415 can be substantially in a range of about 30 Å to about 1000 Å, preferably, substantially in a range of about 50 Å to about 200 Å.

In FIG. 4B, a gate 420 is formed on a portion of the first vanadium oxide layer 415 by sputtering and patterning. The gate 420 can be a metal layer comprising Cu, Al, Mo, Ag, Ag—Pd—Cu, Cr, W, Ti, metal alloy thereof or multi-layer thereof. A second vanadium oxide layer 425 is then formed on the first vanadium oxide layer 415 and the gate 420 by CVD or PVD. The thickness of the second vanadium oxide layer 425 can be substantially in a range of about 30 Å to about 1000 Å, preferably, substantially in a range of about 50 Å to about 200 Å. That is, the gate 420 is surrounded by vanadium oxide.

In FIG. 4C, a gate-insulating layer 430 is formed on the second vanadium oxide layer 425 by, for example, CVD or PVD. The gate-insulating layer 430 can be a silicon oxide, silicon nitride, silicon oxynitride, tantalum oxide or aluminum oxide layer. The gate-insulating layer 430 can also be an organic layer with a protective function. The organic layer may comprise a compound containing Si, O and C, a compound containing Si, O, C and H, a compound containing Si and C, a compound containing C and F, or a substantially starburst-shaped compounds containing center of C or F. In this case, since the first vanadium oxide layer 415 is between the gate 420 and the substrate 410, the adhesion therebetween is increased. Additionally, since the second vanadium oxide layer 425 is between the gate 420 and the gate-insulating layer 430, the second vanadium oxide layer 425 prevents deformation of the gate 420 during subsequent plasma processes for depositing gate-insulating layers.

In FIG. 4C, a semiconductor layer comprising a channel layer 440 and an ohmic contact layer 450 is formed on a portion of the gate-insulating layer 430 by deposition and patterning. The channel layer 440 can be an amorphous silicon layer formed by CVD. The ohmic contact layer 450 can be an impurity-added silicon layer formed by CVD. The impurity can be n type dopant (for example P or As) or p type dopant (for example B).

In FIG. 4D, a source 460 and a drain 470 are formed on a portion of the semiconductor layer formed by sputtering and patterning. The source 460 and drain 470 can be metal layers comprising Al, Mo, Cr, W, Ta, Ti, Ni, metal alloy thereof, or multi-layer thereof. Using the source 460 and drain 470 as a mask, the exposed ohmic contact layer 450 is then removed by etching. A TFT structure 400 is thus obtained.

The third embodiment of the TFT structure 400 of the present invention, shown in FIG. 4D, comprises a first vanadium oxide layer 415 formed on a substrate 410. A gate 420 is formed on a portion of the substrate 410. A second vanadium oxide layer 425 is formed on the first vanadium oxide layer 415 and the gate 420. A gate-insulating layer 430 is formed on the second vanadium oxide layer 425. A semiconductor layer 440/450 is formed on a portion of the gate-insulating layer 430. A source 460 and a drain 470 are formed on a portion of the semiconductor layer 440/450.

When the TFT structure 400 is applied in the TFT-LCD panel, the gate 420 and the gate line of the array substrate can be formed simultaneously. Thus, the first and second vanadium oxide layers 415 and 425 can also be formed between the gate line and the substrate 410 and between the gate line and the gate-insulating layer 430. To avoid obscuring aspects of the disclosure, description of detailed formation of the TFT-LCD panel is omitted here.

It should-be noted that the vanadium oxide layer of the disclosure can also be adaptable to the source/drain of the TFT structure. For example, the vanadium oxide layer overlies the source/drain, thereby preventing the deformation thereof during subsequent plasma processes.

The embodiments thin film transistor structures. A vanadium oxide layer is formed between the gate and the substrate and/or the gate and the gate-insulating layer. Thus, the gate has exceptional adhesion with the substrate by means of the vanadium oxide layer. In addition, the vanadium oxide layer prevents deformation of the gate during subsequent plasma processes, increasing device yield.

While the invention has been described by way of example and in terms of preferred embodiment, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A thin film transistor (TFT), comprising:
a substrate;
a first vanadium oxide layer formed on the substrate;
a gate formed on the first vanadium oxide layer;
a gate-insulating layer formed on the gate;
a semiconductor layer formed on a portion of the gate-insulating layer; and
a source and a drain formed on a portion of the semiconductor layer.

2. The TFT according to claim 1, further comprising a second vanadium oxide layer formed between the gate and the gate-insulating layer.

3. The TFT according to claim 2, wherein the thickness of at least one of the first vanadium oxide layer and the second vanadium oxide layer is substantially in a range of about 30 Å to about 1000 Å.

4. The TFT according to claim 1, wherein the gate comprises Cu, Al, Mo, Ag, Ag—Pd—Cu, Cr, W, Ti, metal alloy thereof, or multi-layer thereof.

5. The TFT according to claim 1, wherein the gate-insulating layer comprises silicon oxide, silicon nitride, silicon oxynitride, tantalum oxide, aluminum oxide, a compound containing Si, O and C, a compound containing Si, O, C and H, a compound containing Si and C, a compound containing C and F, a substantially starburst-shaped compounds containing center of C, or a substantially starburst-shaped compounds containing center of F.

6. The TFT according to claim 1, wherein the semiconductor layer comprises silicon, and the source and the drain comprise Al, Mo, Cr, W, Ta, Ti, Ni, metal alloy thereof, or multi-layer thereof.

7. A thin film transistor (TFT), comprising:
a substrate;
a gate formed on the substrate;
a vanadium oxide layer formed on the gate;
a gate-insulating layer formed on the vanadium oxide layer;
a semiconductor layer formed on a portion of the gate-insulating layer; and
a source and a drain formed on a portion of the semiconductor layer.

8. The TFT according to claim 7, wherein the gate comprises Cu, Al, Mo, Ag, Ag—Pd—Cu, Cr, W, Ti, metal alloy thereof, or multi-layer thereof.

9. The TFT according to claim 7, wherein the thickness of the vanadium oxide layer is substantially in a range of about 30 Å to about 1000 Å.

10. The TFT according to claim 7, wherein the gate-insulating layer comprises silicon oxide, silicon nitride, silicon oxynitride, tantalum oxide, aluminum oxide, a compound containing Si, O and C, a compound containing Si, O, C and H, a compound containing Si and C, a compound containing C and F, a substantially starburst-shaped compounds containing center of C, or a substantially starburst-shaped compounds containing center of F.

11. The TFT according to claim 7, wherein the semiconductor layer comprises silicon, and the source and the drain comprise Al, Mo, Cr, W, Ta, Ti, Ni, metal alloy thereof, or multi-layer thereof.

12. A method of forming a thin film transistor, comprising the steps of:
providing a substrate;
forming a first vanadium oxide layer on the substrate;
forming a gate on the first vanadium oxide layer;
forming a gate-insulating layer on the gate;
forming a semiconductor layer on a portion of the gate-insulating layer; and
forming a source and a drain on a portion of the semiconductor layer.

13. The method according to claim 12, further comprising forming a second vanadium oxide layer between the gate and the gate-insulating layer.

14. The method according to claim 13, wherein the thickness of at least one of the first vanadium oxide layer and the second vanadium oxide layer is substantially in a range of about 30 Å to about 1000 Å.

15. The method according to claim 12, wherein the gate comprises Cu, Al, Mo, Ag, Ag—Pd—Cu, Cr, W, Ti, metal allay thereof, or multi-layer thereof.

16. The method according to claim 12, wherein the gate-insulating layer comprises silicon oxide, silicon nitride, silicon oxynitride, tantalum oxide, aluminum oxide, a compound containing Si, O and C, a compound containing Si, O, C and H, a compound containing Si and C, a compound containing C and F, a substantially starburst-shaped compounds containing center of C, or a substantially starburst-shaped compounds containing center of F.

17. The method according to claim 12, wherein the semiconductor layer comprises silicon, and the source and the drain comprise Al, Mo, Cr, W, Ta, Ti, Ni, metal alloy thereof, or multi-layer thereof.

18. A method of forming a thin film transistor, comprising the steps of:
providing a substrate;
forming a gate on the substrate;
forming a vanadium oxide layer on the gate;
forming a gate-insulating layer on the vanadium oxide layer;
forming a semiconductor layer on a portion- of the gate-insulating layer; and
forming a source and a drain on a portion of the semiconductor layer.

19. The method according to claim 18, wherein the gate comprises Cu, Al, Mo, Ag, Ag—Pd—Cu, Cr, W, Ti, metal alloy thereof, or multi-layer thereof.

20. The method according to claim 18, wherein the thickness of the vanadium oxide layer is substantially in a range of about 30 Å to about 1000 Å.
